(19) United States
(12) Patent Application Publication
(10) Pub. No.: US 2004/0040492 A1
(43) Pub. Date: Mar. 4, 2004

(54) Substrate and manufacturing method therefor

(76) Inventor: Kiyofumi Sakaguchi, Kanagawa (JP)

Correspondence Address: FITZPATRICK CELLA HARPER & SCINTO, 30 ROCKEFELLER PLAZA, NEW YORK, NY, 10112, US

(21) Appl. No.: 10/653,949

(22) Filed: Sep. 4, 2003

(30) Foreign Application Priority Data
Sep. 4, 2002 (JP) 2002-258971

(51) Int. Cl. C30B 23/00; C30B 25/00; C30B 28/12; C30B 28/14

(52) U.S. Cl. 117/84; 117/89

(57) ABSTRACT

A partial SOI substrate is obtained by performing a step of forming a partial insulating layer on the first substrate, a step of selectively growing the first semiconductor layer on an exposed portion of the first substrate, a step of growing the second semiconductor layer in the partial insulating layer on the first semiconductor layer, and a step of forming a bonded substrate by bonding the second substrate to the second semiconductor layer of the first substrate.

### FIELD OF THE INVENTION

The present invention relates to a substrate and manufacturing method therefor and, more particularly, to a substrate which has a partial insulating layer inside and a manufacturing method therefor.

### BACKGROUND OF THE INVENTION

Conventionally, a method of forming a partial oxide film on a surface of single-crystal silicon is known. This method is useful to, e.g., an embedded IC in which a logic circuit is formed in the SOI region on an SOI substrate, and a DRAM using a trench-type capacitor is formed in the non-SOI region. This is because the trench-type capacitor generally needs to have a depth of about several μm (about 10 μm or less) and thus is not formed on an Si layer of the SOI substrate having a thickness of about 100 nm. To form a partial oxide film on a surface of single-crystal silicon, Japanese Patent Laid-Open No. 1-144665 discloses a semiconductor device manufacturing method in which an insulating film is formed in a predetermined region of a semiconductor substrate, a polysilicon layer and an epitaxial layer are simultaneously formed on the insulating layer and the single-crystal Si substrate, respectively.

In the method disclosed in Japanese Patent Laid-Open No. 1-144665, however, the height of the grown surface of the polysilicon layer is larger than that of the grown surface of the epitaxial layer, and thus the region of the polysilicon layer extends to the region of the epitaxial layer. The extension of the polysilicon layer region to the epitaxial layer region causes a formation of single-crystal silicon instead of polysilicon region near the boundary between the polysilicon layer and the epitaxial layer, thereby narrowing the region of the epitaxial layer available for a device manufacturing. For example, in the case of a formation of trench-type capacitor in the epitaxial layer, the capacitor must not be formed in a region where the polysilicon layer is extended, and the epitaxial layer region in a partial oxide film cannot be fully utilized. More specifically, the extension of the polysilicon layer to the epitaxial layer interferes with a larger device integration.

In the method disclosed in Japanese Patent Laid-Open No. 1-144665, a bulk substrate is employed as an SOI layer. For this reason, the thickness of the SOI layer is extremely large, and the advantage of introducing the SOI substrate decreases. Although an Si layer of the SOI substrate is polished in the above method, a trench-type capacitor is formed through an N⁻-Si layer, N⁺-Si layer, a plurality of epitaxial layers, and N⁺-Si substrate. Consequently, the characteristics degrade particularly at the interface between different layers.

### SUMMARY OF THE INVENTION

The present invention has been made in consideration of the above-mentioned problems, and has as its object to, e.g., effectively ensure a region for manufacturing a device.

According to the first aspect of the present invention, there is provided a semiconductor manufacturing method comprising a step of forming a partial insulating layer on a first substrate, a step of selectively growing a first semiconductor layer on an exposed portion of the first substrate in the partial insulting layer, a step of growing a second semiconductor layer on the partial insulating layer and first semiconductor layer, and a step of forming a bonded substrate by bonding the second substrate to the second semiconductor layer of the first substrate.

According to a preferred embodiment of the present invention, the method preferably further comprises a step of forming a separation layer on the first substrate, and a step of splitting the bonded substrate at the separation layer after the step of forming the bonded substrate.

According to a preferred embodiment of the present invention, in the step of growing the first semiconductor layer, the first semiconductor layer is preferably grown in a single crystal.

According to a preferred embodiment of the present invention, in the step of growing the first semiconductor layer, the first semiconductor layer is preferably grown to have a thickness larger than a thickness of the insulating layer.

According to a preferred embodiment of the present invention, in the step of growing the second semiconductor layer, a single-crystal layer is preferably grown on the first semiconductor layer, and a polycrystalline or amorphous layer is grown on the insulating layer.

According to a preferred embodiment of the present invention, in the step of growing the second semiconductor layer, the polycrystalline or amorphous layer is preferably grown such that a region of the polycrystalline or amorphous layer falls within a range of the insulating layer.

According to the second aspect of the present invention, there is provided a substrate which can be manufactured by the above manufacturing method.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1A is a view for explaining a substrate manufacturing method according to the first embodiment of the present invention;

FIG. 1B is a view for explaining the substrate manufacturing method according to the first embodiment of the present invention;

FIG. 1C is a view for explaining the substrate manufacturing method according to the first embodiment of the present invention;

FIG. 1D is a view for explaining the substrate manufacturing method according to the first embodiment of the present invention;

FIG. 1E is a view for explaining the substrate manufacturing method according to the first embodiment of the present invention;

FIG. 1F is a view for explaining the substrate manufacturing method according to the first embodiment of the present invention;

FIG. 1G is a view for explaining the substrate manufacturing method according to the first embodiment of the present invention;

FIG. 2 is a view showing another structure of a substrate according to the first embodiment of the present invention;

FIG. 3A is a view for explaining a substrate manufacturing method according to the second embodiment of the present invention;

FIG. 3B is a view for explaining the substrate manufacturing method according to the second embodiment of the present invention;

FIG. 3C is a view for explaining the substrate manufacturing method according to the second embodiment of the present invention;

FIG. 3D is a view for explaining the substrate manufacturing method according to the second embodiment of the present invention;

FIG. 3E is a view for explaining the substrate manufacturing method according to the second embodiment of the present invention;

FIG. 3F is a view for explaining the substrate manufacturing method according to the second embodiment of the present invention;

FIG. 3G is a view for explaining the substrate manufacturing method according to the second embodiment of the present invention;

FIG. 3H is a view for explaining the substrate manufacturing method according to the second embodiment of the present invention;

FIG. 3I is a view for explaining the substrate manufacturing method according to the second embodiment of the present invention; and

FIG. 3J is a view for explaining the substrate manufacturing method according to the second embodiment of the present invention.

### DETAILED DESCRIPTION OF THE PREFERRED EMBODIMENTS

Preferred embodiments of the present invention will be described below with reference to the accompanying drawings.

### First Embodiment

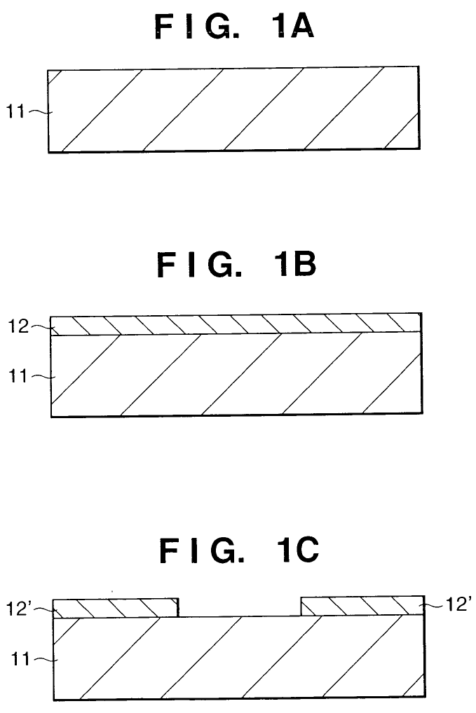

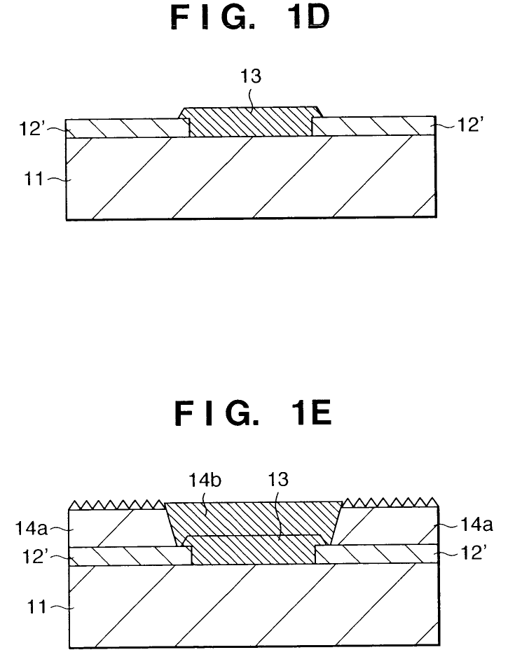

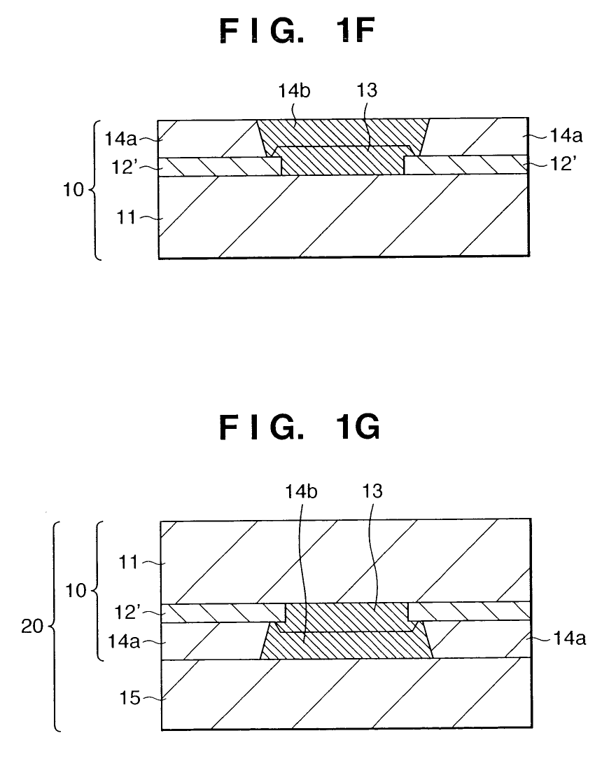

FIGS. 1A to 1G are views for explaining a substrate manufacturing method according to a preferred embodiment of the present invention. In the step shown in FIG. 1A, a substrate (seed substrate) 11 is prepared, and in the step shown in FIG. 1B, an oxide film 12 serving as an insulating layer is formed on the substrate 11. The substrate 11 includes a single-crystal semiconductor of one of Ge, SiGe, SiC, C, GaAs, AlGaAs, InGaAs, InP, InAs, and the like in addition to single-crystal silicon. Although the oxide film 12 can be formed by, e.g., thermal oxidation, the present invention is not limited to this. Plasma oxidation, liquid phase growth, chemical vapor deposition (CVD), or the like may be used instead. Generally, an oxide film of good quality can be formed by thermal oxidation. An insulting layer may be formed using any other insulating material such as a nitride film, instead of the oxide film 12.

In the step shown in FIG. 1C, for example, after the oxide film 12 is coated with a resist, it is patterned by lithographic process to form an opening. Part of the oxide film 12 which is exposed at the bottom of the opening is etched by dry etching such as RIE (reactive ion etching) or wet etching using, e.g., a chemical solution. With this operation, a partial oxide film 12′ is formed on the single-crystal Si layer 11. A partial oxide film is defined as an oxide film which is formed such that the single-crystal Si substrate 11 is at least partially exposed.

In the step shown in FIG. 1D, a single-crystal Si layer (first semiconductor layer) 13 is selectively grown on an exposed portion of the single-crystal Si substrate 11 in the partial oxide film 12′. The single-crystal Si layer 13 is preferably grown so as to have a thickness larger than that of the partial oxide film 12′.

In the step shown in FIG. 1E, Si layers (second semiconductor layers) 14a and 14b are grown on the partial oxide film 12′ and single-crystal Si layer 13. At this time, the single-crystal layer 14b is grown on the single-crystal Si layer 13 while the polycrystalline layer or amorphous layer 14a is grown on the partial oxide film 12′. The presence of the single-crystal Si layer (first semiconductor layer) 13 causes the polycrystalline layer or amorphous layer 14a to grow within a region on the partial oxide film 12′. More specifically, the region of the polycrystalline layer or amorphous layer 14a does not extend to the region of the single-crystal Si layer 13 in the partial oxide film 12′. Consequently, the region of the single-crystal Si layer 13 and single-crystal layer 14b can effectively be utilized to manufacture a deep device.

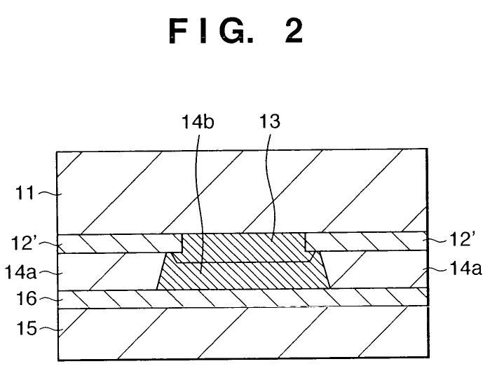

In the step shown in FIG. 1F, the surface of a first substrate 10 shown in FIG. 1E is planarized by polishing, grinding, or the like. Then, in the step shown in FIG. 1G, a second substrate (handle substrate) 15 is bonded to the surface (a surface in which the polycrystalline layer or amorphous layer 14a and single-crystal layer 14b are exposed) of the first substrate 10 shown in FIG. 1F to form a bonded substrate 20. Note that an insulating layer (e.g., an oxide film) 16 may be formed on the surface of the first substrate 10 or the second substrate (handle substrate) 15 prior to the bonding, as shown in FIG. 2. As the second substrate 15, an Si substrate, a substrate obtained by forming an insulating layer (e.g., an oxide film) on an Si substrate, an optically transparent substrate of, e.g., quartz, a sapphire substrate, or the like is preferably used. Since the second substrate 15 needs to be arranged such that a surface to be bonded is flat, a substrate of any other type may be adopted. Although a substrate having a structure shown in FIG. 1F is referred to as the first substrate for the sake of convenience, a substrate having a structure shown in any one of FIGS. 1A to 1F also may be referred to as the first substrate.

As described above, according to the substrate manufacturing method of this embodiment, the region of a polycrystalline or amorphous layer does not extend to the region of a single-crystal Si layer in a partial oxide film. For this reason, a region for manufacturing a device can effectively be ensured.

### Second Embodiment

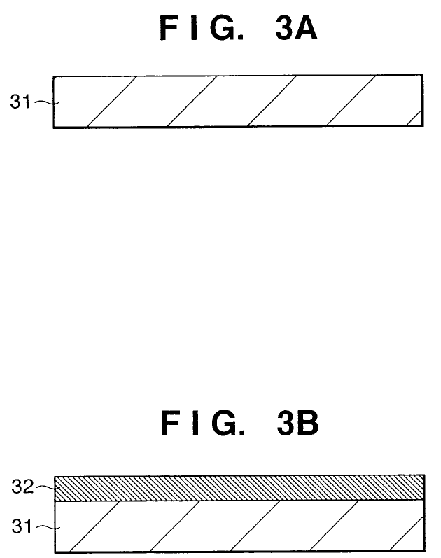

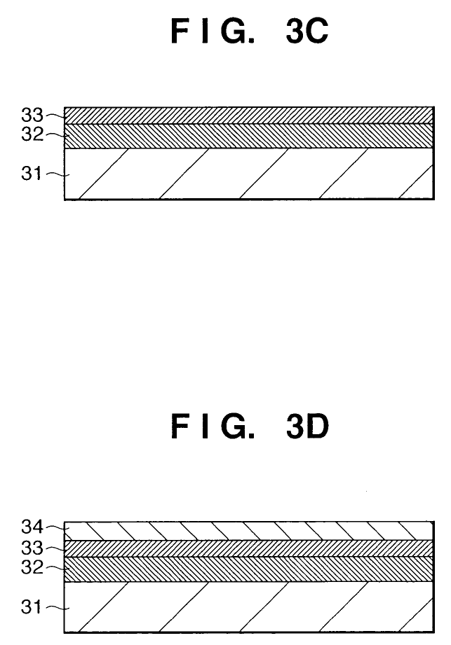

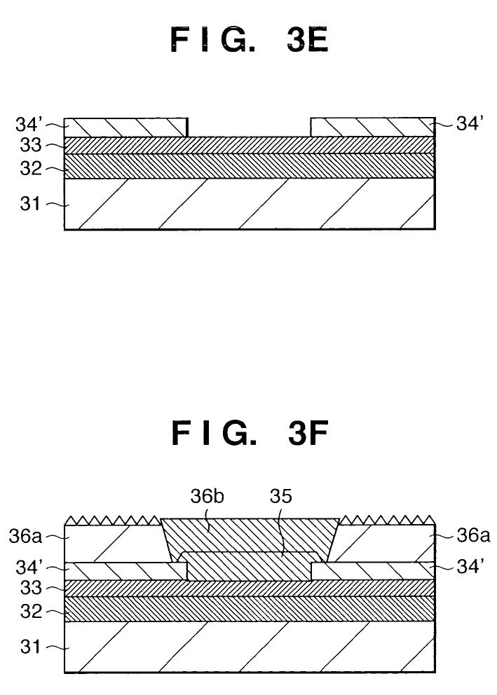

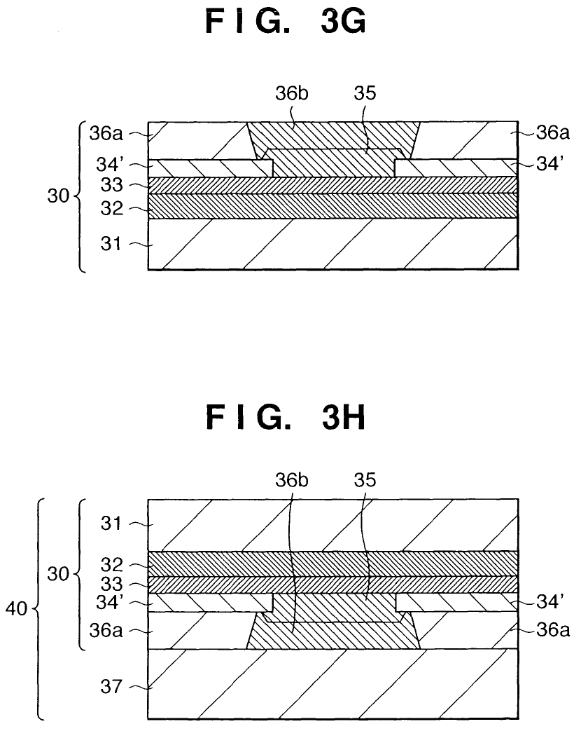

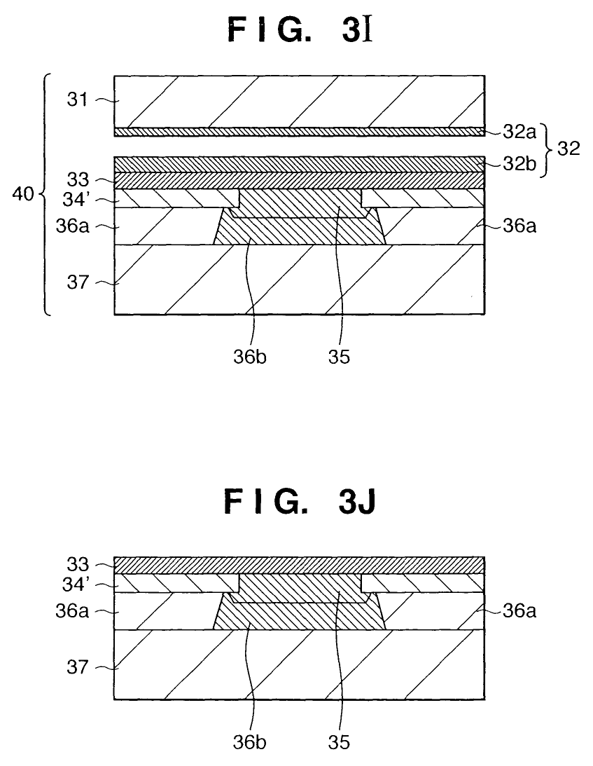

FIGS. 3A to 3J are views for explaining a substrate manufacturing method according to the second preferred embodiment of the present invention. In the step shown in FIG. 3A, a single-crystal Si substrate (seed substrate) 31 is prepared, and in the step shown in FIG. 3B, a separation layer 32 is formed on the surface of the single-crystal Si substrate 31. As the separation layer 32, a porous layer formed by anodizing the surface of the single-crystal Si substrate 31 is preferably used. This anodization can be performed by, e.g., placing an anode and cathode in an electrolyte solution containing hydrofluoric acid, placing the single-crystal Si substrate 31 between the electrodes, and supplying a current between them. The porous layer may comprise two or more layers with different porosities.

In the step shown in FIG. 3C, a single-crystal Si layer 33 is formed on the separation layer 32 by epitaxial growth. Epitaxial growth can form the single-crystal Si layer 33 of good quality.

In the step shown in FIG. 3D, an oxide film 34 serving as an insulating layer is formed on the single-crystal Si layer 33. The oxide film 34 can be formed by, e.g., thermal oxidation. Although thermal oxidation can form an oxide film of good quality, the present invention is not limited to this. Plasma oxidation, liquid phase growth, or the like may be used instead. An insulting layer may be formed using any other insulating material such as a nitride film, instead of the oxide film 34.

In the step shown in FIG. 3E, for example, after the oxide film 34 is coated with a resist, it is patterned by lithography to form an opening. Part of the oxide film 34 which is exposed at the bottom of the opening is etched by dry etching such as reactive ion etching (RIE) or wet etching using, e.g., a chemical solution. With this operation, a partial oxide film 34′ is formed on the single-crystal Si layer 33. A partial oxide film is defined as an oxide film which is formed such that the single-crystal Si substrate 33 is at least partially exposed.

In the step shown in FIG. 3F, a single-crystal Si layer (first semiconductor layer) 35 is selectively grown on an exposed portion of the single-crystal Si layer 33 in the partial oxide film 34′. The single-crystal Si layer 35 is preferably grown so as to have a thickness larger than that of the partial oxide film 34′. Si layers (second semiconductor layers) 36a and 36b are grown on the partial oxide film 34′ and single-crystal Si layer 35. At this time, the single-crystal layer 36b is grown on the single-crystal Si layer 35 while the polycrystalline layer or amorphous layer 36a is grown on the partial oxide film 34′. The presence of the single-crystal Si layer (first semiconductor layer) 35 causes the polycrystalline layer or amorphous layer 36a to grow within a region on the partial oxide film 34′. More specifically, the region of the polycrystalline layer or amorphous layer 36a does not extend to the region of the single-crystal Si layer 35, which is encircled by the partial oxide film 34′. Consequently, the region of the single-crystal Si layer 35 and single-crystal layer 36b can effectively be utilized to manufacture a deep device.

In the step shown in FIG. 3G, the surface of a first substrate 30 shown in FIG. 3F is planarized by polishing, grinding, or the like. Then, in the step shown in FIG. 3H, a second substrate (handle substrate) 37 is bonded to the surface (a surface in which the polycrystalline layer or amorphous layer 36a and single-crystal layer 36b are exposed) of the first substrate 30 shown in FIG. 3G to form a bonded substrate 40. Note that an insulating layer (e.g., an oxide film) may be formed on the surface of the first substrate 30 prior to the bonding. As the second substrate 37, an Si substrate, a substrate obtained by forming an insulating layer (e.g., an oxide film) on an Si substrate, an optically transparent substrate of, e.g., quartz, a sapphire substrate, or the like is preferably used. Since the second substrate 15 needs to be arranged such that a surface to be bonded is flat, a substrate of any other type may be adopted. Although a substrate having a structure shown in FIG. 3G is referred to as the first substrate for the sake of convenience, a substrate having a structure shown in any one of FIGS. 3A to 3F may also be referred to as the first substrate.

In the step shown in FIG. 3I, the bonded substrate 40 is split into two substrates by splitting the bonded substrate 40 at the separation layer 32. This splitting can be performed by, e.g., using a fluid. As a method of using a fluid, a method of forming a jet of a fluid (liquid or gas) and injecting it to the separation layer 32, a method of utilizing the static pressure of a fluid, or the like is preferably used. Among these methods, a method of utilizing water as a fluid is referred to as a water jet method. The above-mentioned splitting can also be performed by, e.g., annealing the bonded substrate 40. Such splitting by annealing is particularly effective in forming an ion implantation layer as the separation layer 32. Additionally, the splitting can be performed by, e.g., inserting a member such as a solid wedge into the separation layer 32.

In addition to the above-mentioned splitting methods, a grinding and polishing method in which the back surface (exposed surface) of the bonded substrate 40 is ground and polished to leave a single-crystal Si layer with a predetermined thickness on the insulating film 34′ may be adopted. In this case, the separation layer 32 need not be formed in advance.

In the step shown in FIG. 3J, a separation layer 32b left on the single-crystal Si layer 33 is removed using an etchant or the like. At this time, the single-crystal Si layer 33 can be used as an etching stopper layer. Then, the surface of the substrate may be planarized by performing a planarizing step such as a hydrogen annealing step, polishing step, or the like, as needed.

As described above, according to the substrate manufacturing method of this embodiment, a single-crystal Si layer formed on a separation layer is used as an SOI layer. For this reason, the thickness of the SOI layer can be reduced. Additionally, since a trench-type capacitor is not so formed as to extend through a plurality of layers, the characteristics of the substrate can be prevented from degrading at an interface between different layers.

### EXAMPLES

Preferred examples of the present invention will be described below.

### Example 1

First, a first single-crystal Si substrate 11 of p-type or n-type having a resistivity of 0.01 to 0.02 Ω·cm was prepared (this corresponds to the step shown in FIG. 1A).

Then, an oxide film 12 having a thickness of 200 nm was formed on the surface of the single-crystal Si substrate 11 by thermal oxidation (this corresponds to the step shown in FIG. 1B).

A mask material (preferably, SiN or the like) was deposited on the oxide film 12, and a resist was further applied to its surface. These materials were sequentially patterned such that an opening was formed in a non-SOI region (or a thick-SOI region in which a thick SOI layer is formed). Since this example uses a bonding method (e.g., ELTRAN: a registered trademark) in which the first substrate and second substrate are bonded together, patterning must be so performed as to form a mirror image of a normal pattern.

If a mask material is not deposited on the oxide film 12, a resist is applied to the oxide film 12 and is patterned to form a resist pattern. Then, the oxide film 12 is etched through an opening of the resist pattern to expose the single-crystal Si substrate 11.

On the other hand, if a mask material is deposited on the oxide film 12, a resist is applied to the mask material and is patterned to form a resist pattern. Then, the mask material is etched through an opening of the resist pattern, thereby performing patterning for the mask material. The oxide film 12 is etched through an opening of the mask material until the single-crystal Si substrate 11 is exposed, thereby performing patterning for the oxide film 12. At this time, the resist may be removed after the patterning of the mask material and before the patterning of the oxide film 12.

When the resist and mask material were removed, a substrate in which the single-crystal Si substrate 11 was partially exposed was obtained (this corresponds to the step shown in FIG. 1C).

A step (corresponding to the step shown in FIG. 1D) of selectively and epitaxially growing a single-crystal Si layer 13 (first semiconductor layer) on an exposed portion of the single-crystal Si substrate 11 in a partial oxide film 12′ and a step (corresponding to the step shown in FIG. 1E) of non-selectively depositing Si layers (second semiconductor layers) 14a and 14b were sequentially performed. The the single-crystal Si layer 13 preferably has a thickness larger than that of the partial oxide film 12′. At this time, the single-crystal layer 14b was grown on the single-crystal Si layer 13 while the polycrystalline layer or amorphous layer 14a was grown on the partial oxide film 12′. The thicknesses of the second semiconductor layers 14a and 14b can appropriately be determined in accordance with specifications required by a final semiconductor substrate. For example, the thicknesses can be set to about 10 μm. In the above-mentioned manner, the polycrystalline layer or amorphous layer 14a was formed only on the oxide film 12 without extending to an opening of the oxide film.

Then, the surface of the substrate was planarized by polishing (this corresponds to the step shown in Fig. IF). As the polishing step, CMP may be performed. To remove any portion damaged by polishing in the polishing step, a cleaning step and/or etching step may further be performed.

The surface of a first substrate 10 and that of a second Si substrate 15 separately prepared were overlaid on and brought into contact with each other. After that, both the substrates were subjected to annealing in a nitrogen atmosphere or oxygen atmosphere at 1,100° C. for 1 hr to increase the bonding strength between the first substrate 10 and the second substrate 15 (this corresponds to the step shown in FIG. 1G). With this operation, a bonded substrate 20 was obtained.

If an oxide film is formed on at least one of the surface of the first substrate 10 and that of the second substrate 15, a region in which the second epitaxial Si layer (second semiconductor layer) 14b is grown becomes not a non-SOI region but a thick-SOI region (See FIG. 2). The thickness of the silicon film in the thick-SOI region can appropriately be determined in accordance with specifications required by a final semiconductor substrate. For example, the thickness can be set to about 10 μm.

If an oxide film as described above is not formed, a region without any partial oxide film has not an SOI structure but the same structure as that of an epitaxial wafer (See FIG. 1G).

If plasma processing is performed for at least one of respective surfaces to be bonded of the first and second substrates as a preprocess of the bonding step, the bonding strength can be increased even by annealing at a low temperature. Additionally, a substrate having undergone plasma processing is preferably cleaned.

Note that the first semiconductor layer 13 and second semiconductor layers 14a and 14b may be made of, e.g., SiGe, GaAs, GaAs, SiC, C, or the like, instead of silicon (Si). As the second substrate 15, a substrate made of, e.g., quartz, sapphire, ceramic, carbon, SiC, or the like may be adopted, in addition to an Si substrate.

### Example 2

First, a first single-crystal Si substrate 31 of p-type or n-type having a resistivity of 0.01 to 0.02 Ω·cm was prepared (this corresponds to the step shown in FIG. 3A).

Then, the single-crystal Si substrate 31 was anodized in an anodizing solution, thereby forming a porous Si layer serving as a separation layer 32. The anodizing conditions were as follows.

Current density: 7 (mA·cm⁻^{²})

Anodizing solution: HF:H₂O:C₂H₅OH=1:1:1

Time: 11 (min)

Thickness of porous silicon portion: 12 (μm)

The current density and the concentrations of the respective components of the anodizing solution can appropriately be changed in accordance with the thickness, structure, and the like of the separation layer (porous Si layer) 32 to be formed. Preferably, the current density falls within the range of 0 to 700 mA/cm², and the ratio between the concentrations of the above components of the anodizing solution falls within the range of 1:10:10 to 1:0:0.

The porous Si layer is useful because a high-quality epitaxial Si layer is formed thereon and the porous Si layer functions as a separation layer. If the first and second substrates are bonded together to form a bonded substrate, and then the bonded substrate is ground to remove part of the first substrate, the porous Si layer need not be used as a separation layer.

The anodizing solution needs to contain HF but need not contain ethanol. Ethanol, however, is useful for removing any air bubbles from the surface of the substrate and is preferably added to the anodizing solution. Examples of a chemical agent which has a function of removing air bubbles include, e.g., alcohols such as methyl alcohol and isopropyl alcohol, a surfactant, and the like in addition to ethanol. Instead of adding these chemical agents, air bubbles may be eliminated from the substrate surface by vibrations of ultrasonic waves or the like.

The thickness of the porous Si layer is not limited to the above example. Satisfactory results can be obtained as far as the thickness falls within the range of, e.g., several hundred μm to 0.1 μm.

The anodized substrate was oxidized in an oxygen atmosphere at 400° C. for 1 hr. With this oxidizing step, the inner walls of pores of the porous Si layer were covered with a thermally oxidized film.

A single-crystal Si layer 33 having a thickness of 0.3 μm is epitaxially grown on the porous Si layer by chemical vapor deposition (CVD) (this corresponds to the step shown in FIG. 3C). The growth conditions were as follows.

Source gas: SiH₂Cl₂/H₂

Gas flow rate: 0.5/180 L/min

Gas pressure: 80 Torr

Temperature: 950° C.

Growth rate: 0.3 μm/min

Note that these growth conditions can appropriately be changed in accordance with required specifications of the single-crystal Si layer 33.

Prior to the epitaxial growth step, the substrate may be baked in an epitaxial reactor in a hydrogen atmosphere, and/or a minimum amount of silicon source may be supplied to the substrate in the epitaxial reactor. Then, the pores in the surface of the porous Si layer may be filled to planarize the substrate. By performing such an additional step, an epitaxial layer having a minimum defect density (10⁴ cm⁻² or less) could be formed on the porous Si layer.

An oxide film 34 having a thickness of 200 nm was formed on the epitaxial Si layer 33 by thermal oxidation (this corresponds to the step shown in FIG. 3D).

A mask material (preferably, SiN or the like) was deposited on the oxide film, and a resist was further applied to its surface. These materials were sequentially patterned such that an opening was formed in a non-SOI region (or a thick-SOI region). Since this example uses a bonding method (e.g., ELTRAN: a registered trademark) in which the first substrate and second substrate are bonded together, patterning must be so performed as to form a mirror image of a normal pattern.

If a mask material is not deposited on the oxide film 34, a resist is applied to the oxide film 34 and is patterned to form a resist pattern. Then, the oxide film 34 is etched through an opening of the resist pattern to expose the epitaxial Si layer 33.

On the other hand, if a mask material is deposited on the oxide film 34, a resist is applied to the mask material and is patterned to form a resist pattern. Then, the mask material is etched through an opening of the resist pattern, thereby performing patterning for the mask material. The oxide film 34 is etched through an opening of the mask material until the epitaxial Si layer 33 is exposed, thereby performing patterning for the oxide film 34. At this time, the resist may be removed after the patterning of the mask material and before the patterning of the oxide film 34.

When the resist and mask material were removed, a substrate in which the epitaxial Si layer 33 was partially exposed was obtained (this corresponds to the step shown in FIG. 3E).

A step of selectively and epitaxially growing a single-crystal Si layer 35 (first semiconductor layer) on an exposed portion of the epitaxial Si layer 33 and a step of unselectively depositing semiconductor layers (second semiconductor layers) 36a and 36b were sequentially performed (this corresponds to the step shown in FIG. 3F). The semiconductor layer 36b selectively grown on the single-crystal Si layer 35 preferably has a thickness larger than that of a partial oxide film 34′. At this time, the single-crystal layer 36b was grown on the single-crystal Si layer 35 while the polycrystalline layer or amorphous layer 36a was grown on the partial oxide film 34′. The thicknesses of the semiconductor layers 36a and 36b can appropriately be determined in accordance with specifications required by a final semiconductor substrate. For example, the thicknesses can be set to about 10 μm. In the above-mentioned manner, the polycrystalline layer or amorphous layer 36a was formed only on the partial oxide film 34′ without extending to an opening of the oxide film (this corresponds to the step shown in FIG. 3F). To remove any portion damaged by polishing in a polishing step, a cleaning step and/or etching step may further be performed.

Then, the surface of the substrate was planarized by polishing (this corresponds to the step shown in FIG. 3G). As the polishing step, CMP may be performed. To remove any portion damaged by polishing in the polishing step, a cleaning step and/or etching step may further be performed.

The surface of a first substrate 30 and that of a second Si substrate 37 separately prepared were overlaid on and brought into contact with each other. After that, the both substrates were subjected to annealing in a nitrogen atmosphere or oxygen atmosphere at 1,100° C. for 1 hr to increase the bonding strength between the first substrate 30 and the second substrate 37 (this corresponds to the step shown in FIG. 3H). With this operation, a bonded substrate 40 was obtained.

If an oxide film is formed on at least one of the surface of the first substrate 30 and that of the second substrate 37, a region in which the semiconductor layer 36b is grown becomes not a non-SOI region but a thick-SOI region in which a thick SOI region is formed. The thickness of the silicon film in the thick-SOI region can appropriately be determined in accordance with specifications required by a final semiconductor substrate. For example, the thickness can be set to about 10 μm.

If an oxide film as described above is not formed, a region without any partial oxide film has not an SOI structure but the same structure as that of an epitaxial wafer.

Pure water was injected from a 0.1-mm nozzle of a water jet apparatus toward a concave portion (concave portion formed by the beveled portions of the two substrates 30 and 37) of the periphery of the bonded substrate 40 in a direction parallel to the bonding interface of the bonded substrate 40 at a high pressure of 50 MPa. With this operation, the bonded substrate 40 was split at the separation layer 32 into two substrates (this corresponds to the step shown in FIG. 3I). The pressure of the pure water preferably falls within the range of several MPa to 100 MPa.

In this splitting step, any one of the following operations may be performed.

(1) The nozzle performs scanning such that a jet of pure water injected from the nozzle moves along the concave portion formed by the beveled portions.

(2) The bonded substrate 40 is held by a wafer holder and rotates on its axis to inject pure water into the concave portion formed by the beveled portions around the periphery of the bonded substrate.

(3) The operations (1) and (2) are performed in combination.

Consequently, the polycrystalline or amorphous layer 36a, partial oxide film 34, epitaxial Si layers 35 and 36b, and a part 32a of the porous Si layer 32, which were originally formed on the side of the first substrate 30 were moved to the side of the second substrate 37. Only a porous Si layer 32a was left on the surface of the first substrate 30.

Instead of splitting the bonded substrate by a water jet method, a jet of gas may be used or a solid wedge may be inserted into the separation layer of the bonded substrate. Alternatively, a mechanical force such as a tensile force, shearing force, or the like may be applied to the bonded substrate or ultrasonic waves may be applied to the bonded substrate. In addition, any other method may be adopted.

Moreover, out of the two substrates constituting the bonded substrate, a portion from the back surface of the first base 40 to the porous Si layer may be removed by grinding, polishing, etching, or the like without splitting the bonded substrate, thereby exposing the entire surface of the porous silicon layer.

At this time, any one of the following operations may be performed.

(1) A portion from the exposed surface of the first substrate of the bonded substrate to the porous Si layer is continuously ground.

(2) A portion from the exposed surface of the first substrate of the bonded substrate is continuously ground until just before reaching the porous Si layer, and the remaining bulk silicon portion is removed by dry etching such as RIE or wet etching.

(3) A portion from the exposed surface of the first substrate of the bonded substrate is continuously ground until just before reaching the porous Si layer, and the remaining bulk silicon portion is removed by polishing.

The porous Si layer 32b which was moved to the uppermost surface of the second substrate 37 was selectively etched using an etchant in which at least a 49% hydrofluoric acid solution, a 30% hydrogen peroxide solution, and water are mixed (this corresponds to the step shown in FIG. 3J). The single-crystal Si layer 33 was left unetched. The porous Si layer 32b was selectively etched using the single-crystal Si layer 33 as an etch stopper and completely removed. If selective etching is performed while starting/stopping generating ultrasonic waves using an apparatus combined with a circulator and rotating a wafer, non-uniform etching in the surface and among substrates can be suppressed. Additionally, if alcohol or a surfactant is mixed with the etchant, unevenness in etching caused by gaseous reaction products on the surface can be suppressed.

The etching speed of a non-porous single-crystal Si layer with the etchant is extremely low, and the selectivity ratio to the etching speed of a porous layer reaches 10⁵ or more. The etching amount (about several ten Å) in a non-porous layer reduces the film thickness by a substantially negligible amount.

With the above-mentioned steps, a semiconductor substrate which has the single-crystal Si layer 33 with a thickness of 0.2 μm on the partial oxide film 34′ and single-crystal Si layer 35 in the partial oxide film 34′ was obtained. Although the porous Si layer was selectively etched, no change occurred in the single-crystal Si layer 33. When the film thickness of the formed single-crystal Si layer 33 was measured at 100 points across the surface, the uniformity of the film thickness was 201 nm±4 nm.

The observation of the cross section with a transmission electron microscope showed that the single-crystal Si layer 33 had no additional crystal defects and maintained good crystallinity.

Furthermore, the substrate was subjected to annealing (hydrogen annealing) in a hydrogen atmosphere at 1,100° C. for 1 hr, and the surface roughness was evaluated with an atomic force microscope. The root-mean-square roughness in a 50-inch-square region was about 0.2 nm, which was equivalent to that of a commercially available silicon wafer.

The surface may be planarized by polishing such as CMP, instead of hydrogen annealing.

If plasma processing is performed for at least one of respective surfaces to be bonded of the first and second substrates as a preprocess of the bonding step, the bonding strength can be increased even by annealing at a low temperature. Additionally, a substrate having undergone plasma processing is preferably rinsed by pure water.

In the splitting step, a plurality of bonded substrates may be arranged in their planar direction, and a nozzle of a water jet apparatus may perform scanning along the planar direction, thereby continually splitting the plurality of bonded substrates.

Alternatively, a plurality of bonded substrates may be arranged in a direction perpendicular to each plane, and a nozzle of a water jet apparatus may be provided with an X-Y scanning function. Then, a jet of water may sequentially be injected toward a plurality of bonding portions of the bonded substrate, and the bonded substrates may automatically and continually be split.

The single-crystal Si layer 33, semiconductor layer 35, and second semiconductor layers 36a and 36b may be made of, e.g., SiGe, GaAs, GaAs, SiC, C, or the like, instead of silicon (Si).

As the second substrate 37, a substrate made of, e.g., quartz, sapphire, ceramic, carbon, SiC, or the like may be adopted, in addition to an Si substrate.

### Example 3

This example is an improved example of the example 2 and is the same as the example 2 except for anodizing conditions.

In this example, a single-crystal Si substrate 31 was prepared and anodized in a solution containing HF under either of the following anodizing conditions.

First Anodizing Condition

(First Step)

Current density: 8 (mA·cm⁻^{²})

Anodizing solution: HF:H₂O:C₂H₅OH=1:1:1

Time: 11 (min)

Thickness of porous silicon portion: 13 (μm)

(Second Step)

Current density: 22 (mA·cm⁻^{²})

Anodizing solution: HF:H₂O:C₂H₅OH=1:1:1

Time: 2 (min)

Thickness of porous silicon portion: 3 ( μm)

or

(Second Anodizing Condition)

(First Step)

Current density: 8 (mA·cm⁻^{²})

Anodizing solution: HF:H₂O:C₂H₅OH=1:1:1

Time: 5 (min)

Thickness of porous silicon portion: 6 (μm)

(Second Step)

Current density: 33 (mA·cm⁻^{²})

Anodizing solution: HF:H₂O:C₂H₅OH=1:1:1

Time: 1.3 (min)

Thickness of porous silicon portion: 3 (μm)

The first porous Si layer to be formed at the first step of the anodization is used to form a high-quality epitaxial Si layer thereon. The second porous Si layer to be formed under the first porous Si layer at the second step of the anodization is used as a separation layer. Note that if the first substrate is removed by grinding a bonded substrate, a porous Si layer is not used as a separation layer.

The position of a separation surface (a surface to be separated) was limited to the vicinity of the interface between the first porous Si layer and second porous Si layer. This was effective in planarization of the separation surface.

### Example 4

A DRAM having a trench capacitor was formed in the non-SOI region of a semiconductor substrate which was manufactured by each of the methods described in the examples 1 to 3 and had a structure shown in FIG. 1G or 3J. Other devices including a logic circuit were formed in the SOI region. In the methods described in the examples 1 to 3, the surface of a semiconductor substrate to be manufactured is flat. For this reason, in the lithography step, the entire region of exposure shots fell within the focus-range of the depth of a projection optical system, and no local defocusing (defocusing due to unevenness of the surface of the substrate) occurred. Since a single-crystal Si layer having a sufficient thickness was formed in the non-SOI region, no trouble occurred in forming the trench capacitor.

Additionally, the above semiconductor substrate is effectively used to form an integrated circuit other than a DRAM-embedded one.

### Other Example

Various film forming techniques such as CVD, MBE, sputtering, liquid phase growth can be applied to the epitaxial growth step for forming a single-crystal Si layer, the first semiconductor layer, and the second semiconductor layer in each of the above examples. Also, various other etchants (e.g., a mixture of a hydrofluoric acid solution, nitric acid solution, and acetic acid solution) can be applied to the step of selectively etching a separation layer (porous layer, ion implantation layer, or the like) left upon splitting, in addition to a mixture of a 49% hydrofluoric acid solution, a 30% hydrogen peroxide solution, and water as described above. In the above-mentioned manner, a region for forming a deep device can be enlarged in a wafer which has non-SOI and SOI regions or SOI regions with different thicknesses.

According to the present invention, a region for forming a device can effectively be ensured.

As many apparently widely different embodiments of the present invention can be made without departing from the spirit and scope thereof, it is to be understood that the invention is not limited to the specific embodiments thereof except as defined in the appended claims.

What is claimed is:

1. A semiconductor manufacturing method comprising:
a step of forming a partial insulating layer on a first substrate;
a step of selectively growing a first semiconductor layer on an exposed portion of the first substrate in the partial insulting layer;
a step of growing a second semiconductor layer on the partial insulating layer and first semiconductor layer; and
a step of forming a bonded substrate by bonding the second substrate to the second semiconductor layer of the first substrate.

2. The method according to claim 1, further comprising:
a step of forming a separation layer on the first substrate; and
a step of splitting the bonded substrate at the separation layer after the step of forming the bonded substrate.

3. The method according to claim 1, wherein in the step of growing the first semiconductor layer, the first semiconductor layer is grown in a single crystal.

4. The method according to claim 1, wherein in the step of growing the first semiconductor layer, the first semiconductor layer is grown to have a thickness larger than a thickness of the partial insulating layer.

5. The method according to claim 1, wherein in the step of growing the second semiconductor layer, a single-crystal layer is grown on the first semiconductor layer, and a polycrystalline or amorphous layer is grown on the partial insulating layer.

6. The method according to claim 5, wherein in the step of growing the second semiconductor layer, the polycrystalline or amorphous layer is grown such that a region of the polycrystalline or amorphous layer falls within a range of the insulating layer.

7. A substrate manufactured by the manufacturing method as defined in claim 1.
